(19) United States
(12) Patent Application Publication
(10) Pub. No.: US 2002/0058198 A1
(43) Pub. Date: May 16, 2002

(54) Fluorinated phenolic polymers and photoresist compositions comprising same

(75) Inventors: Axel Klauck-Jacobs, Allentown, PA (US); Anthony Zampini, Westborough, MA (US); Sungseo Cho, Milford, MA (US); Shintaro Yamada, Marlborough, MA (US)

Correspondence Address: Peter F. Corless, EDWARDS & ANGELL, LLP, Dike, Bronstein, Roberts & Cushman, IP Group, P.O. Box 9169, Boston, MA, 02209, US

(73) Assignee: Shipley Company, L.L.C., Marlborough, MA

(21) Appl. No.: 09/948,521

(22) Filed: Sep. 8, 2001

Related U.S. Application Data
(60) Provisional application No. 60/231,274, filed on Sep. 8, 2000.
(60) Provisional application No. 60/253,118, filed on Nov. 27, 2000.

(51) Int. Cl. G03F 7/038

(52) U.S. Cl. 430/270.1; 430/272.1; 430/325; 430/326; 526/247; 526/242; 568/755; 568/592

(57) ABSTRACT

The present invention includes polymers and photoresist compositions that comprise the polymers as a resin binder component. Photoresists of the invention contain a polymer that has fluorinated phenolic units and photoacid-labile groups. Resists of the invention can be effectively imaged at short wavelengths such as sub-200 nm, particularly 157 nm.

This application claims the benefit of U.S. provisional application No. 60/231,274 filed Sep. 8, 2000, and U.S. provisional application No. 60/253,118, filed Nov. 27, 2000, both incorporated herein by reference.

### BACKGROUND OF THE INVENTION

1. Field of the Invention

The present invention relates to new polymers comprising electronegative groups and use of such polymers as a resin binder component for photoresist compositions, particularly chemically-amplified positive-acting resists that can be effectively imaged at short wavelengths such as sub-200 nm and preferably about 157 nm. Resins of resists of the invention contain fluorinated phenolic units.

2. Background

Photoresists are photosensitive films used for transfer of images to a substrate. A coating layer of a photoresist is formed on a substrate and the photoresist layer is then exposed through a photomask to a source of activating radiation. The photomask has areas that are opaque to activating radiation and other areas that are transparent to activating radiation. Exposure to activating radiation provides a photoinduced chemical transformation of the photoresist coating to thereby transfer the pattern of the photomask to the photoresist-coated substrate. Following exposure, the photoresist is developed to provide a relief image that permits selective processing of a substrate.

A photoresist can be either positive-acting or negative-acting. For most negative-acting photoresists, those coating layer portions that are exposed to activating radiation polymerize or crosslink in a reaction between a photoactive compound and polymerizable reagents of the photoresist composition. Consequently, the exposed coating portions are rendered less soluble in a developer solution than unexposed portions. For a positive-acting photoresist, exposed portions are rendered more soluble in a developer solution while areas not exposed remain comparatively less developer soluble. Photoresist compositions are described in Deforest, Photoresist Materials and Processes, McGraw Hill Book Company, New York, ch. 2, 1975 and by Moreau, Semiconductor Lithography, Principles, Practices and Materials, Plenum Press, New York, ch. 2 and 4.

While currently available photoresists are suitable for many applications, current resists also can exhibit significant shortcomings, particularly in high performance applications such as formation of highly resolved sub-half micron and sub-quarter micron features.

Consequently, interest has increased in photoresists that can be photoimaged with short wavelength radiation, including exposure radiation of about 250 nm or less, or even about 200 nm or less, such as wavelengths of about 193 nm. Use of such short exposure wavelengths can enable formation of smaller features. Accordingly, a photoresist that yields well-resolved images upon 248 nm or 193 nm exposure could enable formation of extremely small (e.g. sub-0.25 μm) features that respond to constant industry demands for smaller dimension circuit patterns, e.g. to provide greater circuit density and enhanced device performance.

### SUMMARY OF THE INVENTION

We have now provide new photoresist compositions that can provide highly resolved relief images upon exposure to extremely short wavelengths, particularly sub-200 nm wavelengths, and even sub-170 nm or sub-160 nm wavelengths such as 193 nm and 157 nm. The polymers of the invention also are useful for resists imaged at higher wavelengths such as sub-300 nm, particularly sub-260 nm such as e.g. 248 nm.

Polymers for use in the resists of the invention contain repeat units of fluorinated phenolic groups and photoacid-labile deblocking groups. A fluorinated phenolic group has one or more fluorine-containing ring substituents, such as F, fluoroalkyl, particularly fluorinated alkyl having 1 to about 8 carbons including perfluoroalkyl such as —CF₃. Such groups may be provided e.g. by polymerization of a fluorinated vinylphenol.

We have surprisingly found that resins with such fluorophenolic units can exhibit good transparency at extremely short wavelengths such as sub-200 nm, particularly 157 mn.

The polymers of the invention also suitably contain one or more of a variety of other repeat units.

Preferred polymers of the invention are copolymers (i.e. at least two distinct repeat units that comprise repeat units of 1) fluorinated phenolic groups, and 2) acid labile groups, e.g. an acid-labile ester, acetal, ketal, formyl group (—O—CH₂—O), ether or other group. Esters or acrylate-based photoacid-labile deblocking groups are especially preferred for such copolymers, e.g. as may be provided by polymerization of t-butylacrylate, t-butylmethacrylate, t-butyl trifluoromethylacrylate, methyladamantylacrylate, methyladamantylmethacrylate, methyladamantyltrifluoromethylacrylate, ethyladamantylacrylate, ethyladamantylnethacrylate, ethyladamantyltrifluoromethylacrylate, and the like.

Polymers of the invention may contain other repeat units, such as phenyl groups that are not substituted by hydroxy or carboxy (e.g. —COOH) or a photoacid-labile groups, but may contain other ring substituents such as electronegative groups, including halogen particularly fluoro, haloalkyl, such as halo(C₁₋₈alkyl), particularly fluoro(C₁₋₈alkyl) including perfluoroalkyl such as —CF₃, nitro, alkylsulfonyl, alkylsulfonyl, and the like. Fluoro and fluoroalkyl particularly perfluoro(C₁₋₈alkyl) are generally preferred.

Other suitable repeat units of the polymers of the invention include cyano (such as may be provided e.g. by polymerization of acrylonitrile or methacrylonitrile), a carbon alicyclic group having either an exocyclic or endocyclic double bond such as optionally substituted norbornene, optionally substituted vinyladamantyl, optionally substituted cyclohexene, and the like.

Preferred polymers of the invention include higher order polymers, i.e. terpolymers (three distinct repeat units), tetrapolymers (four distinct repeat units) and pentapolymers (five distinct repeat units).

Particularly preferred higher order polymers include those that contain repeat units of: 1) fluorinated phenolic units; 2) phenyl units that do not contain hydroxy or carboxy or acid-labile ring substituents, but preferably contain one or more electronegative ring substituents such as halo particularly fluoro or haloalkyl particularly fluoroalkyl such as —CF₃; and 3) a photoacid-labile group, e.g. an acid-labile ester, acetel, ketal, formyl group (—O—CH₂—O), ether or other group. Esters or acrylate-based photoacid-labile deblocking groups are especially preferred for such copolymers, e.g. as may be provided by polymerization of t-butylacrylate, t-butylmethacrylate, t-butyl trifluoromethylacrylate, methyladamantylacrylate, methyladamantylmethacrylate, and the like. It is understood that units 2) may comprise hydroxy or carboxy substitution where the hydroxy or carboxy is not a direct ring substituents, e.g. units 2) are inclusive of (CH₂═CH)C₆H₄(CH(OH)(CF₃)₂).

Additional preferred repeat units of polymers used in resists of the invention include fluorinated unsaturated compounds, e.g. tetrafluoroethylene (Teflon), fluorinated alcohols such as to provide a hexafluoropropyl group and the like. Such compounds may be co-polymerized with a fluorinated phenolic monomer and other monomers such as an acrylate compound comprising a photoacid-labile ester.

Polymers of the invention thus may comprise electronegative substitution on the polymer backbone. For example, the polymer backbone may be substituted with one or more halogens such as fluoro, or a haloalkyl, particularly haloC₁₋₈alkyl such as fluoroC₁₋₈alkyl e.g. —CF₃. Such electronegative backbone substitution may be provided e.g. polymerization of a monomer that has electronegative substitution of olefinic carbons, such as tetrafluoroethylene.

The invention also contains blends of resins and photoresists that contain such resin blends. Preferred resin blends of the invention comprise: 1) a polymer that contains fluorinated phenolic units, preferably in combination with other repeat units such as units that comprise photoacid labile group, and 2) polymers that are substantially free of aromatic units (e.g. less than 5, 4, 3, 2 or 1 mole percent aromatic units) and preferably comprise alicyclic units such as norbonyl, adamantyl and the like, which contain one or more electronegative substituents such as halogen and haloalkyl substituents discussed immediately above with respect to polymers 1) of the blend. Suitable polymers of type 2) of such resin blends include those disclosed in PCT/US99/21912. The relative amounts of polymers of types 1) and 2) in a blend may suitably vary relatively widely, e.g. 10 parts by weight of an aromatic polymer of type 1) relative to 1 part by weight of a non-aromatic polymer of type 2), to 10 parts by weight of a non-aromatic polymer of type 2) to I pat by weight of an aromatic polymer of type 1).

Other preferred resin blend members also contain two distinct polymers, each of the polymers having aromatic units preferably substituted with electronegative groups such as halogen, particularly fluoro, or haloalkyl, particularly fluoro(C₁₋₈alkyl) as discussed above, with at least one of the polymers comprising fluorinated phenolic units.

The invention also provides methods for forming relief images, including methods for forming a highly resolved relief image such as a pattern of lines where each line has essentially vertical sidewalls and a line width of about 0.40 microns or less, and even a width of about 0.25, 0.20 or 0.16 microns or less. The invention further provides articles of manufacture comprising substrates such as a microelectronic wafer substrate or liquid crystal display or other flat panel display substrate having coated thereon a polymer, photoresist or resist relief image of the invention.

The invention also includes new monomer compounds that are particularly useful for synthesis of resins of the invention. These monomers compounds are alkenetetrafluorophenol and protected alkenetetrafluorophenols such as C₆F₄(OH)(C₂₋₁₂alkene), preferably C₆F₄(OH)(C₂₋₆alkene), particularly vinyltetrafluorophenol, which may be protected with an alkyl, ester, ether, acetal or other groups. The alkene substituents also may be fluorinated, e.g. by substitution of olefenic carbons by —F, —CF₃, —CHF₂, and the like. References herein to such alkene moieties are inclusive of fluorinated alkenes. Typical protecting groups are present on the phenolic hydroxy group and are photoacid-labile groups such as those disclosed herein. Particularly preferred monomer compounds are 4-hydroxy-2,3,5,6-tetrafluorostyrene, 3-hydroxy-2,4,5,6-tetrafluorostyrene, 4-hydroxy-2,3,5,6-tetrafluoro(α-methylstyrene), 3-hydroxy-2,4,5,6-tetrafluoro(α-methylstyrene), 4-hydroxy-2,3,5,6-tetrafluoro(α-trifluoromethylstyrene), and 3-hydroxy-2,4,5,6-tetrafluoro(α-trifluoromethylstyrene), and the corresponding compounds where the phenolic hydroxy groups are protected with an ester, acetal, alkyl or the like. References herein to “protected” alkenetetrafluorophenols indicate the phenolic hydroxy group is covalently linked to another group typically to a carbon atoms to provide an ether, ester, acetal or the like.

Other aspects of the invention are disclosed infra.

### BRIEF DESCRIPTION OF THE DRAWINGS

FIG. 1 shows the SEM image of the developed resist of Example 14 which follows.

### DETAILED DESCRIPTION OF THE INVENTION

As discussed above, polymers for use in the resists of the invention contain fluorinated phenolic units.

The fluorinated phenolic groups are suitably provided by reaction of an alkenefluorophenol monomer. A preformed phenolic polymer also may be fluorinated. Resins of the invention also may contain fluorinated novolak (phenol-formaldehyde condensates) structures. Preferred novolaks are trifluoromethyl substituted phenol-formaldehyde condensation products, particularly 3-trifluoromethylphenol-formaldehyde condensation products.

The polymer preferably contains additional units, particularly photoacid-labile units, such as may be provided by polymerization of an alkyl acrylate e.g. t-butylacrylate or t-butylmethacrylate, t-butyl a-trifluoromethyl acrylate, methyladamantylacrylate, methyladamantylmethacrylate and the like. Other acid-labile groups also will be suitable such as acetals, ketals, formyl and other groups. The polymer also may contain other units, such as optionally substituted styrene units, and polymerized vinyl monomers such as polymerized optionally substituted norbornyl, optionally substituted vinyl adamantyl, and fluorinated unsaturated compounds such as tetrafluoroethylene, and the like.

A polymer also may comprises acid-labile groups as a substituent of the fluorinated phenolic group, although generally more preferred is where the photoacid-labile group is present on a repeat unit separate from the fluorinated phenolic group. In systems where a photoacid-labile group is present on a fluorinated phenolic group, the acid-labile groups may be e.g. an acetal or ester group grafted onto the phenolic —OH group. See U.S. Pat. No. 5,258,257 to Sinta et al. for procedures for functionalizing a resin phenolic group with an acid-labile moiety.

Preferred resists of the invention include those that contain a polymer that incorporates a fluoroalcohol, particularly hexafluoroisopropanol. A fluoroalcohol is generally incorporated into a polymer via polymerization of a corresponding vinyl monomer. Such monomers are commercially available or can be readily prepared. For instance, vinyl hexafluoroisopropanol (VHFIP) as shown below. Also preferred is use of the hexafluoroalcohol monomer having an additional methylene (CH₂) group adjacent to the vinyl group (i.e. CH₂═CHCH₂C(CF₃)₂OH), which can be made with the corresponding Grignard reagent (i.e. CH₂═CHCH₂MgBr).

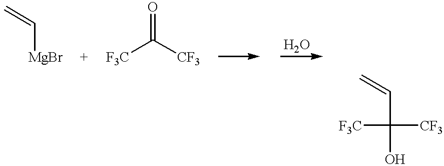

Preferred resins of the invention include those that contain repeat units provide by any one or more of acrylonitrile (AN, I), vinyl hexafluoroisopropanol (VHFI, II) and allyl hexafluoroisopropanol (AHFI, III).

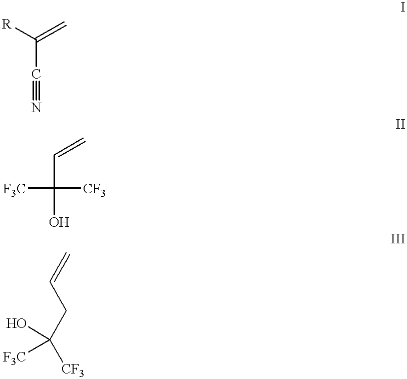

In structure I, R is suitably —H, —CH₃, —F, —CF₃ and the like.

Additional preferred monomers for synthesis of resins of the invention include the following compounds 1, 2, 3 and 4:

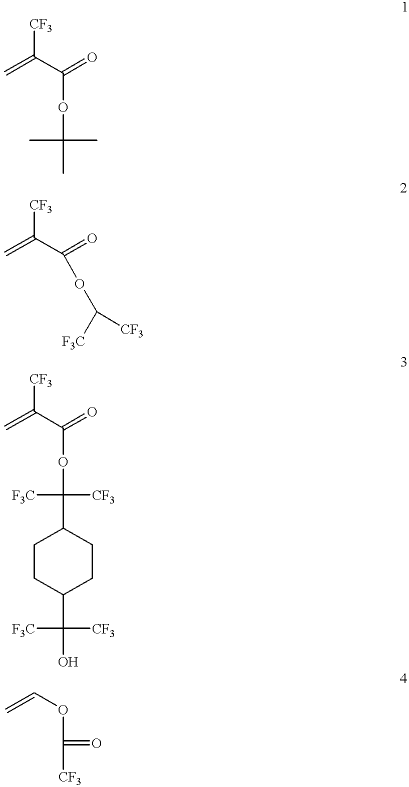

Polymers of the invention can be prepared by a variety of methods. One suitable method is an addition reaction which may include free radical polymerization, e.g., by reaction of selected monomers to provide the various units as discussed above in the presence of a radical initiator under an inert atmosphere (e.g., N₂ or argon) and at elevated temperatures such as about 70° C. or greater, although reaction temperatures may vary depending on the reactivity of the particular reagents employed and the boiling point of the reaction solvent (if a solvent is employed). Suitable reaction solvents include e.g. tetrahydrofuran, ethyl lactate and the like. Suitable reaction temperatures for any particular system can be readily determined empirically by those skilled in the art based on the present disclosure. A variety of free radical initiators may be employed. For example, azo compounds may be employed such as azo-bis-2,4-dimethylpentanenitrile. Peroxides, peresters, peracids and persulfates also could be employed.

Monomer compounds of the invention also can be readily prepared. For instance, an alkenetetrafluorophenol can be prepared by reaction of the corresponding alkenepentafluorobenzene compound with strong base such as a hydroxide and t-butanol. See Example 18 which follows for an exemplary procedure. The formed alkenetetrafluorophenol can be protected, e.g. the phenolic hydroxy can be reacted with an alkylating agent (e.g. an alkyl halide such as MeI) to provide an alkyl ether or an ester.

Alternatively, an alkenephenol can be fluorinated to provide the tetrafluoro ring substitution. Suitably, the alkene group is protected during the fluorination reaction.

As discussed, various moieties of polymers and monomers may be optionally substituted, including substitutents of the tetrafluorphenols of the invention. A “substituted” substituent may be substituted at one or more available positions, typically 1, 2, or 3 positions by one or more suitable groups such as e.g. halogen (particularly F, Cl or Br); C₁₋₈ alkyl; C₁₋₈ alkoxy; C₂₋₈ alkenyl; C₂₋₈ alkynyl; hydroxyl; alkanoyl such as a C₁₋₆alkanoyl e.g. acyl and the like; etc.

Preferred substitution groups will generally include or consist of at least one halogen atom, preferably fluorine such as fluorinated lower alkyl, perfluoroalkyl, and perfluoroalkylene, fluorinated cycloalkyl, and fluorinated ethers and esters including fluorinated cyclic ethers and fluorinated cyclic esters.

Examples of alkyl and lower alkyl include methyl, ethyl, propyl, butyl, pentyl, hexyl and the like, preferably methyl, ethyl and propyl. Suitably alkyl and lower alkyl groups will contain from 1 to about 8 carbon atoms, more typically 1 to about 6 carbon atoms.

Suitable alkylsulfonyl groups will have one or more sulfinyl (SO) moieties and from 1 to about 12 carbon atoms, more typically 1 or 2 sulfinyl moieties and from 1 to about 6 carbon atoms such as —S(O)CH₃. Suitable alkylsulfonyl groups will have one or more sulfonyl (SO₂) moieties and from 1 to about 12 carbon atoms, more typically 1 or 2 sulfonyl moieties and from 1 to about 6 carbon atoms such as —S(O₂)CH₃.

Preferred optionally substituted styrene and substituted styrene groups will be substituted with one or more electronegative groups such as a halogen, particularly fluorine at available ring position. Substituted vinylphenol is a preferred styrene group. Fluorovinylphenol including monofluorophenol (—C₆H₃FOH), difluorophenol (—C₆H₂F₂OH), trifluorophenol (—C₆HF₃OH), and tetrafluorophenol (—C₆F₄OH) are preferred polymer units.

Preferably a polymer of the invention will have a weight average molecular weight (Mw) of about 800 or 1,000 to about 100,000, more preferably about 2,000 to about 30,000, still more preferably from about 2,000 to 15,000 or 20,000, with a molecular weight distribution (Mw/Mn) of about 3 or less, more preferably a molecular weight distribution of about 2 or less. Molecular weights (either Mw or Mn) of the polymers of the invention are suitably determined by gel permeation chromatography.

Polymers of the invention used in photoresist formulations should contain a sufficient amount of photogenerated acid labile ester groups to enable formation of resist relief images as desired. For instance, suitable amount of such acid labile ester groups will be at least 1 mole percent of total units of the polymer, more preferably about 2 to 40, 50, 60 or 70 mole percent, still more typically about 3 to 30, 40, 50, 60 or 70 mole percent of total polymer units. See the examples which follow for exemplary preferred polymers.

A variety of photoacid-labile groups may be employed in resists of the invention as discussed above. For instance, phenolic groups of polymers of the invention may be reacted with vinyl ethers such as ethyl vinyl ethyl ether to provide a photoacid-labile acetal group. Photoacid-labile ester groups such as provided by polymerization of t-butyl methacrylate or t-butyl trifluoromethylacrylate also may be co-polymerized with other polymer units.

Preferred copolymers and other higher order polymers (e.g. terpolymers, tetrapolymers, pentapolymers) of the invention will contain from about 2 to 90 mole percent fluorinated phenolic units based on total polymer units, and from 2 to about 50 mole percent photoacid-labile units such as polymerized alkyl acrylate units, and from 0 to 10 to 80 mole percent of other polymer units such as fluorinated phenyl units that do not contain hydroxy, carboxy or other acid or photoacid-labile groups e.g. polymerized pentafluorostyrene units. More preferred are polymers that contain from about 10 to 70 mole percent fluorinated phenolic units based on total polymer units, and from 5 to about 40 mole percent photoacid-labile units such as polymerized alkyl acrylate units, and from 5 to 50 mole percent of other polymer units such as fluorinated phenyl units that do not contain hydroxy, carboxy or other acid or photoacid-labile groups e.g. polymerized pentafluorostyrene units. Still more preferred are polymers that contain from about 15 to 50 or 60 mole percent fluorinated phenolic units based on total polymer units, and from 5 or 10 to about 25, 30, 35 or 40 mole percent photoacid-labile units such as polymerized alkyl acrylate units, and from 10 to 25, 30, 35, 40 or 50 mole percent of other polymer units such as fluorinated phenyl units that do not contain hydroxy, carboxy or other acid or photoacid-labile groups e.g. polymerized pentafluorostyrene units.

The invention also includes homopolymers of fluorinated phenolic units. In such homopolymers, acid labile groups are suitably present on a portion of the phenolic units, e.g. from about 2 to 60 mole percent of total polymer units will contain acid-labile units, more typically from about 5 or 10 to about 50 mole percent of total polymer units will contain acid labile units.

As discussed above, the polymers of the invention are highly useful as a resin component in photoresist compositions, particularly chemically-amplified positive resists. Photoresists of the invention in general comprise a photoactive component and a resin component that comprises a polymer as described above.

The resin component is suitably used in an amount sufficient to render a coating layer of the resist developable with an aqueous alkaline developer.

Preferred resist compositions of the invention also comprise a photoacid generator (i.e. “PAG”) that is suitably employed in an amount sufficient to generate a latent image in a coating layer of the resist upon exposure to activating radiation. As discussed, a wide variety of photoacid generators (PAGs) can be used with the present invention, including both ionic and non-ionic photoacid generator compounds.

More particularly, preferred PAGS for use in resists of the invention include onium salt compounds including iodonium and sulfonium compounds; and non-ionic PAGs such as imidosulfonate compounds, N-sulfonyloxoimide compounds; diazosulfonyl compounds and other sulfone PAGs including α,α-methylenedisulfones and disulfonehydrazines, nitrobenzyl compounds, halogenated particularly fluorinated non-ionic PAGs. Preferred PAGs for use in resists of the invention also include those that do not have aromatic substitution.

Specifically suitable PAGs include the following, where the depicted iodonium and sulfonium compounds may suitably have any of the depicted counter anions.

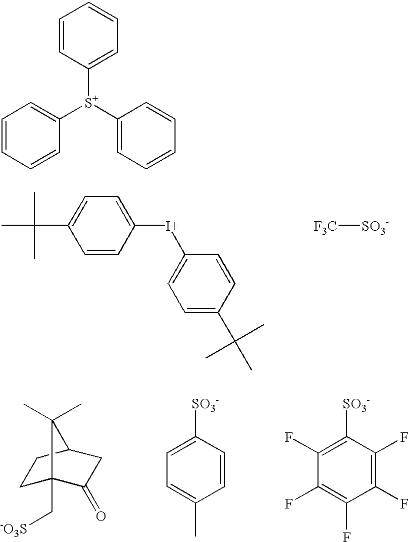

Suitable PAGs for use in resists of the invention also include imidosulfonates such as compounds of the following formula:

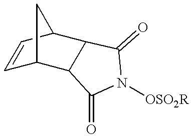

wherein R is camphor, adamantane, alkyl (e.g. C₁₋₁₂ alkyl) and perfluoroalkyl such as perfluoro(C₁₋₁₂alkyl), particularly perfluorooctanesulfonate, perfluorononanesulfonate and the like. A specifically preferred PAG is N-[(perfluorooctanesulfonyl)oxy]-5-norbornene-2,3-dicarboximide. An additional preferred PAG for use in the resists of the invention is triphenylsulfonium perfluorobutyl sulfonate salt.

Other known PAGS also may be employed in the resists of the invention. Particularly for 193 nm imaging, generally preferred are PAGS that do not contain aromatic groups, such as the above-mentioned imidosulfonates, in order to provide enhanced transparency.

A preferred optional additive of resists of the invention is an added base, particularly tetrabutylammonium hydroxide (TBAH), or tetrabutylammonium lactate, which can enhance resolution of a developed resist relief image. For resists imaged at 193 nm, a preferred added base is a hindered amine such as diazabicyclo undecene or diazabicyclononene. The added base is suitably used in relatively small amounts, e.g. about 0.03 to 5 percent by weight relative to the total solids.

Photoresists of the invention also may contain other optional materials. For example, other optional additives include anti-striation agents, plasticizers, speed enhancers, etc. Such optional additives typically will be present in minor concentrations in a photoresist composition except for fillers and dyes which may be present in relatively large concentrations, e.g., in amounts of from about 5 to 30 percent by weight of the total weight of a resist's dry components.

The resists of the invention can be readily prepared by those skilled in the art. For example, a photoresist composition of the invention can be prepared by dissolving the components of the photoresist in a suitable solvent such as, for example, cyclohexanone, 2-heptanone, ethyl lactate, ethylene glycol monomethyl ether, ethylene glycol monomethyl ether acetate, propylene glycol monomethyl ether; propylene glycol monomethyl ether acetate and 3-ethoxyethyl propionate. Typically, the solids content of the composition varies between about 5 and 35 percent by weight of the total weight of the photoresist composition. The resin binder and photoactive components should be present in amounts sufficient to provide a film coating layer and formation of good quality latent and relief images. See the examples which follow for exemplary preferred amounts of resist components.

The compositions of the invention are used in accordance with generally known procedures. The liquid coating compositions of the invention are applied to a substrate such as by spinning, dipping, roller coating or other conventional coating technique. When spin coating, the solids content of the coating solution can be adjusted to provide a desired film thickness based upon the specific spinning equipment utilized, the viscosity of the solution, the speed of the spinner and the amount of time allowed for spinning.

The resist compositions of the invention are suitably applied to substrates conventionally used in processes involving coating with photoresists. For example, the composition may be applied over silicon wafers or silicon wafers coated with silicon dioxide for the production of microprocessors and other integrated circuit components. Aluminum-aluminum oxide, gallium arsenide, ceramic, quartz, copper, glass substrates and the like are also suitably employed.

Following coating of the photoresist onto a surface, it is dried by heating to remove the solvent until preferably the photoresist coating is tack free. Thereafter, it is imaged through a mask in conventional manner. The exposure is sufficient to effectively activate the photoactive component of the photoresist system to produce a patterned image in the resist coating layer and, more specifically, the exposure energy typically ranges from about 1 to 100 mJ/cm², dependent upon the exposure tool and the components of the photoresist composition.

As discussed above, coating layers of the resist compositions of the invention are preferably photoactivated by a short exposure wavelength, particularly a sub-300 and sub-200 nm exposure wavelength, and even sub-170 nm wavelength. As discussed above, 157 nm is a particularly preferred exposure wavelength. However, the resist compositions of the invention also may be suitably imaged at higher wavelengths. For example, a resin of the invention can be formulated with an appropriate PAG and a sensitizer if needed and imaged at higher wavelengths such as about 193 nm or 248 nm.

Following exposure, the film layer of the composition is preferably baked at temperatures ranging from about 70° C. to about 160° C. Thereafter, the film is developed. The exposed resist film is rendered positive working by employing a polar developer, preferably an aqueous based developer such as quaternary ammonium hydroxide solutions such as a tetra-alkyl ammonium hydroxide solution; various amine solutions preferably a 0.26 N tetramethylammonium hydroxide, such as ethyl amine, n-propyl amine, diethyl amine, di-n-propyl amine, triethyl amine, or methyldiethyl amine; alcohol amines such as diethanol amine or triethanol amine; cyclic amines such as pyrrole, pyridine, etc. In general, development is in accordance with procedures recognized in the art.

Following development of the photoresist coating over the substrate, the developed substrate may be selectively processed on those areas bared of resist, for example by chemically etching or plating substrate areas bared of resist in accordance with procedures known in the art. For the manufacture of microelectronic substrates, e.g., the manufacture of silicon dioxide wafers, suitable etchants include a gas etchant, e.g. a halogen plasma etchant such as a chlorine or fluorine-based etchant such a Cl₂ or CF₄/CHF₃ etchant applied as a plasma stream. After such processing, resist may be removed from the processed substrate using known stripping procedures.

All documents mentioned herein are incorporated herein by reference. The following non-limiting examples are illustrative of the invention.

### EXAMPLE 1

### Synthesis of Fluorine Containing Phenolic-formaldehyde Novolak Resin

To a 100 mL 3-necked round bottom flask equipped with a magnetic stirrer, addition funnel, thermometer and oil bath was added 16.2 g of trifluoro-m-cresol and 33 g of 80% sulfuric acid. The mixture was then heated while stirred. At 50° C., 8.93 g of 37% formalin was slowly added over a 12 minute period. During the addition the reaction temperature quickly rose to 81° C. At 93° C. the product begun to precipitated from solution. The mixture was then heated within the temperature range of 99 to 108° C. for about three hours. Upon cooling the aqueous layer was decanted and the product washed with copious amounts of de-mineralized water. The product was then washed with 500 mL de-mineralized water containing 2.5 g of sodium bicarbonate, collected on a filter, rinsed with water and air dried. The solid was then dissolved in 60 g of acetone to produce a clear solution. After the solution was filtered through a glass wool plug it was added drop wise to 500 mL de-mineralized water precipitating the novolak product. The aqueous layer was decanted and the tacky precipitate allowed to partially air dry before fully dried at 40° C. under vacuum. About 18.4 g of product was recovered having a weight average molecular weight of 3650 Daltons and a polydispersity of 1.98.

### EXAMPLE 2

### Use of Fluorinated Novolak

A 5 wt. % solution of the fluorinated novolak of Example 1 was prepared and filtered. The polymer solution was spin coated on CaF₂ disks and silicon wafers. After such coating, the coating layer was baked at 90 seconds at 120° C. The absorbance of the dried polymer layer was obtained by measuring samples of several thicknesses with a vacuum or spectrometer. The normalized absorbance at 157 nm was 4.0 per micron of thickness.

A reference novolak polymer used in the production of I-line photoresists had an absorbance at 157nm of 7.8 per micron thickness.

### EXAMPLE 3

### Photoresist Preparation and Lithographic Processing

A photoresist of the invention is prepared by mixing the following components with amounts expressed as weight percent based on total weight of the resist compositions:

| Resist components | Amount (wt. %) |
|---|---|
| Resin binder | 15 |
| Photoacid generator | 3 |
| Ethyl lactate | 81 |

The resin binder is the fluorinated novolak of Example 4 below. The photoacid generator is p-toluenesulfonyl-trifluoromethanesulfonyl-diazomethane. Those resin and PAG components are admixed in the ethyl lactate solvent.

The formulated resist composition is spin coated onto HMDS vapor primed 4 inch silicon wafers and softbaked via a vacuum hotplate at 90° C. for 60 seconds. The resist coating layer is exposed through a photomask at 248 nm, and then the exposed coating layers are post-exposure baked at 110° C. The coated wafers are then treated with 0.26N aqueous tetramethylammonium hydroxide solution to develop the imaged resist layer and provide a relief image.

### EXAMPLE 4

### Synthesis of 30% Blocked EVE-novolak(trifluoromethyl-substituted)

In a 100 mL three-neck round bottom flask fitted with vacuum distillation apparatus were added 10.00 g (57.47 mmol-eq.) of (trifluoromethyl)-substituted novolak and 30 g of propylene glycol methyl ether acetate (PGMEA). The residual water was removed by azeotropic vacuum distillation with PGMEA at 45° C. (bath temperature). Total 20.97 g of PGMEA was collected in a receiver and a dry ice-vacuum trap. The concentration of the polymer solution was maintained as 25% (w/w). To the reaction solution was added 0.015 g (0.15% w/w of polymer) of trifluoroacetic acid (TFA), and the reaction mixture was stirred for an hour at 20° C. To the reaction mixture was slowly added 1.33 g (18.39 mmol) of ethyl vinyl ether (EVE), and the polymer solution was stirred for 17 h at 20° C. A small quantity (ca. 6 mL) of the reaction solution was sampled and treated with 0.7 g of conditioned IRA-67 ion exchange resin for 2 h.

The solution was filtered and spun onto a silicon wafer to produce a 1455 Å thick film. The film dissolved at a rate of about 22 Å/sec. when immersed into a 0.26N tetramethylammonium hydroxide solution.

### EXAMPLE 5

### Radical Terpolymerization of 4-acetoxystyrene, (trifluoromethyl)-substituted Styrene and t-butyl Acrylate

In a 100 mL three-neck round bottom flask were added 2.83 g (17.43 mmol) of 4-acetoxystyrene, 1.00 g (5.81 mmol) of (trifluoromethyl)-substituted styrene, 0.74 g (5.81 mmol) of t-butyl acrylate and 12 mL of dry isopropyl alcohol (IPA). The reaction vessel was then purged with nitrogen and the reaction mixture was kept under inert atmosphere. The reaction solution was then brought to a gentle reflux at 95° C. (bath temperature). To the reaction mixture was added 0.19 g (1.16 mmol, 4 mol % of monomer) of azo-bis-2,2′-isobutyronitrile (AIBN) dissolved in 1.5 mL of anhydrous acetonitrile. The reaction mixture was then refluxed with stirring for 18 h. To the refluxing polymer solution was slowly added 3.13 g (40.67 mmol) of ammonium acetate dissolved in 3 mL of deionized water. The polymer solution becomes slightly hazy but the haziness disappears in an hour. The refluxing was continued for 15 h and the solution was cooled to room temperature. To the polymer solution was added 6.10 g of conditioned IRN-77 acidic ion exchange resin, and the mixture was stirred for 2 h. The polymer solution was then filtered, precipitated in 250 mL of deionized water, and stirred for 2 h. The polymer was filtered, washed with 250 mL of deionized water with stirring for an hour, and filtered and air-dried. Vacuum drying for 24 h at 70° C. gave 3.40 g of white powder. Yield: 74%. Molecular weight: M_{w} 9900 Mₙ 5600 PD 1.75. T_{g}: 139° C. T_{d}: 183° C. . Initial polymerization feed ratio was 60/20/20 (4-acetoxystyrene/(trifluoromethyl)-substituted styrene/t-butyl acrylate) and the determined actual composition was 63/19/18. The terpolymer composition was calculated by quantitative ¹³C NMR experiments.

### EXAMPLE 6

### Synthesis if Tetrahydropyronyl (THP) Protected Fluorine Containing Novolak

In a 100 mL three-neck round bottom flask equipped with a dropping funnel are added 5.00 g (28.74 mmol) of F-Novolak prepared according to the procedure described in Example 1 above (Mw=1400) and 20 mL of ethyl acetate. The mixture is stirred until homogeneous solution is obtained. To the solution are added 2.42 g (28.74 mmol) of dihydropyran and 2 drops of HCl. The reaction mixture is stirred for 24 h at 25° C. The reaction mixture is then diluted with 100 mL of dichloromethane and washed with aqueous NaCl solution and water. The organic phase is then dried over MgSO₄ and the solvent evaporated. Vacuum drying for 48 hours at room temperature gives about 5.20 g (70.2% yield) of a viscous product.

### EXAMPLE 7

### Synthesis of Ethoxymethyl Ether Protected F-novolak

In a 250 mL three-neck round bottom flask equipped with a dropping funnel are added 10.00 g (57.47 mmol) of F-Novolak prepared according to the procedure described in Example 1 and 20 mL of dry THF. The mixture is stirred until a clear solution is obtained. To the solution is added 0.41 g (17.24 mmol) of sodium hydride powder. The mixture is stirred for 3 h at room temperature, followed by slow addition of 1.63 g of chloromethyl ethyl ether in 5 mL of dry THF over a 30 min. period. The reaction mixture is then stirred for 3 h at room temperature before heating up to 70° C. After 24 h, the white salt is removed by filtration and the filtrate is precipitated in 800 mL of deionized water. The collected precipitate is re-dissolved in 200 mL of dichloromethane. The organic phase is washed with two portions of 100 mL of water and dried over sodium sulfate. The solvent is removed by a rotary evaporator and the product further dried for 48 h under vacuum at 40° C. to give 10.9 g of blocked polymer.

### EXAMPLE 8

### Synthesis of 30% Ethyl Vinyl Ether Blocked F-novolak

In a 100 mL three-neck round bottom flask fitted with a vacuum distillation apparatus are added 10.00 g of F-novolak prepared according to the procedure described in Example 1 and 30 g of propylene glycol methyl ether acetate (PGMEA).The residual water is removed by an azeotropic vacuum distillation with PGMEA at 45° C. (bath temperature). Total 20.97 g of PGMEA is collected in a receiver and a dry ice-vacuum trap. The concentration of the polymer solution is maintained at about 25% (w/w). To the reaction solution is added 0.015 g of trifluoroacetic acid (TFA), and the reaction mixture stirred for about an hour at 20° C. To the reaction mixture is slowly added 1.33 g of ethyl vinyl ether (EVE), and the polymer solution stirred for about 17 h at 20° C. The solution is treated with a conditioned IRA-67 ion exchange resin for 2 h. The solution is then filtered and the filtrate concentrated under reduced pressure. Overnight vacuum drying at 40° C. gives about 7.83 g of a brown viscous product in about 69.6% yield. Gel permeation chromatography shows the product to have a weight average molecular weight of 1760 and a number average molecular weight of 1220 Daltons. Vacuum ultraviolet spectroscopic measurements shows the product to have an absorption of about A₁₅₇: 4.55/μm.

### EXAMPLE 9

### Synthesis of Fluorine Containing Novolak Resin Using Methane Sulfonic Acid as Catalyst

To 500 mL resin kettle equipped with an oil bath, paddle stirrer, thermometer and reflux condenser are added 97.2 g (0.6 mole) of trifluoromethyl-m-cresol and 36.7 g of 37% formaldehyde. The mixture is then heated. At about 65° C. about 52.7 g of methanesulfonic acid is gradually added and the addition continued until a reaction exotherm is observed at about 92° C. The batch temperature rises to about 1 14° C. before it begins to decline. The acid addition is then resumed and continued to completion. The reaction mixture is then allowed to reflux for about 4 hours. While the reaction mixture is still hot about 77 g of trifluoromethylbenzene and 200 mL of water containing 3 g of sodium bicarbonate are added and the mixture vigorously agitated. After the aqueous layer is removed the organic solution is washed twice with 200 mL portions of fresh de-mineralized water. The organic solution is then concentrated by distilling away the solvent under atmospheric pressure. The product is further heated to about 150° C. before partial vacuum is applied. At about 170° C. 3 mmHg vacuum is applied until the batch temperature rises to about 200° C. At this point the vacuum is broken with nitrogen and the product poured into an aluminum pan and allowed to cool. About 81.3 g of product is obtained having a weight average molecular weight of about 2460 Dalton and a molecular weight dispersity of about 1.84. The dissolution rate of the resin in 0.26 N tetramethyl ammonium hydroxide is about 15800 Å/sec.

### EXAMPLE 10

### Synthesis of t-BOC Protected F-novolak

To a 250 mL three-neck round bottom flask equipped with a dropping funnel are added 30.00 g of (trifluoromethyl)-substituted novolak of Example 8 and 80 mL of dry THF. The mixture is stirred until a clear solution is obtained. To the solution is added 8.58 g (62.07 mmol) of anhydrous potassium carbonate, followed by the slow addition of 11.29 g (51.72 mmol) of di-t-butyl dicarbonate in 20 mL of dry THF. The reaction mixture is stirred for 48 h at room temperature. The solution is filtered and precipitated in 1500 mL of de-ionized water. The filtered precipitate is dissolved in 300 mL of dichloromethane and washed twice with 200 mL of de-ionized water. The organic phase is dried over anhydrous sodium sulfate and the solvent removed by use of a rotary evaporator. Vacuum drying for 24 h at 45° C. gives 31.5 g of a white solid (90% yield). The dissolution rate of the t-BOC blocked novolak in 0.26N tetramethyl ammonium hydroxide is 1.5 Å/sec.

### EXAMPLE 11

### Photoresist Composition Comprising of t-BOC Protected F-novolak

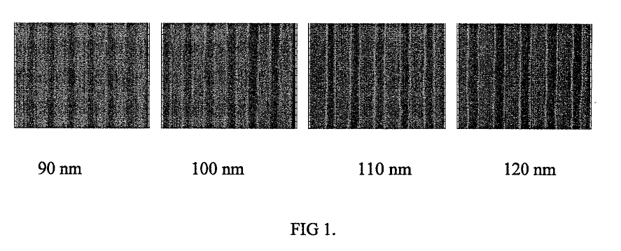

An ethyl lactate solution comprising of 7.312 weight % of a 30% t-BOC protected F-novolak prepared according to the procedure of Example 10, 0.64 weight % di(t-butyl)phenyl iodonium triflate, 0.032 weight % tetrabutylammonium hydroxide, 0.016 weight % of RO8 surfactant and 92 weight % ethyl lactate is filtered through a 0.2 mμ filter and spin coated unto an 8 inch silicon wafer to produce a 680 Å film. The film is soft baked at 80° C. for 60 seconds and exposed to 157 nm radiation using an Exitech 0.60 NA, 0.70s. The exposed film is then post-exposed baked at 80° C. for 60 seconds and then spray developed with LDD-26W tetramethylammonium hydroxide developer, rinsed and dried. The resulting images were then analyzed using scanning electron microscopy. The developed resist images are shown in FIG. 1 of the drawings (semidense lines 1:1.5 pitch).

### EXAMPLES 12-17

The following synthesis Examples 12 to 17 demonstrate an alternative synthesis approach to a fluorinated novolak. This approach employs a two step process: (a) formation of a fluorinated resol intermediate and (b) the acid catalyzed conversion of the resol to the fluorinated novolak of the invention. This approach facilitates the syntheses of a wide range of resin structures and branching densities, resins with higher glass transition temperature, better control of resin molecular weight with minimal trifluoromethyl group hydrolysis.

### EXAMPLE 12

### Synthesis of a Fluorinated Resol

To a 500 mL Erlenmeyer flask is added a solution comprised of 26.0 g of sodium hydroxide and 120 mL of water. To this solution is added, in small portions, 97.2 g (0.6 mole) of 3-(trifluoromethyl)phenol followed with the addition of 146 g of 37% formaldehyde solution. The reaction mixture is heated to 80° C. and kept at this temperature for about 40 hours. While still warm the product solution is filtered and added drop wise into a stirred solution consisting of about 3 L de-ionized water, about 53.4 g of glacial acidic acid and about 10 mL of concentrated hydrochloric acid. The precipitate is collected on a filter, rinsed with water and then soaked for 3 hours in 3 L de-ionized water containing about 5 mL of concentrated hydrochloric acid. The product is collected on a filter, rinsed with water and dried first in air then at 50° C. under vacuum. About 101.7 g of a light beige solid is obtained with a weight average molecular weight of about 1850 Daltons and polydispersity of about 1.84.

The structure and composition of the fluorinated resol can be varied by the formaldehyde feed, reaction temperature and reaction time. Example 13 below is a demonstration of this process versatility.

### EXAMPLE 13

### Synthesis of a Fluorinated Resol

The same reactant ratio and basic procedure of Example 12 are used except that the maximum reaction temperature does not exceed 77° C. and the reaction time is 24 hours. Under these reaction conditions the resulting resin has a weight average molecular weight of 946 Daltons and a polydispersity of 1.43.

### EXAMPLE 14

### Synthesis of a Fluorinated Novolak

The fluorinated resol of Example 12 above was reacted with 3-(trifluoromethyl)phenol. To a 250 mL round bottom flask equipped with a thermometer and an oil bath is added 20 g of resin of Example 12 and 20 g of 3-(trifluoromethyl)phenol. The mixture is heated to 81° C. with mixing until a solution is obtained. To this solution 0.6 g of methanesulfonic acid is added and the mixture kept at about 84° C. for 4 hours. The product mixture is then diluted with about 40 mL of methanol and added drop wise to about 500 mL of de-ionized water containing about 2 g of sodium bicarbonate. The precipitate is collected, rinsed and soaked in 500 mL of de-mineralized water. Again the precipitate is collected, rinsed and partially air dried on the filter before it is placed in a 50° C. vacuum oven to complete the drying process. About 32.5 g of product is recovered having a weight average molecular weight of about 4090 Daltons and a polydispersity of about 3.66.

### EXAMPLE 15

### Synthesis of a Fluorinated Novolak

The resol of Example 13 was self-condensed in the presence of acid. To a solution comprising of 2 g of resol of Example 13 and 4 g of acetic acid is added 0.2 g methanesulfonic acid. The mixture is heated in an oil bath for about 5 hours at a temperature range of 85 to 89° C. The light amber solution is added dropwise, with stirring, to about 50 mL of de-mineralized water. The precipitate is washed and soaked in several 50 mL portions of fresh water. It is then re-dissolved in 10 mL methanol and re-precipitated into 40mL water. A small amount of sodium chloride is added to disrupt the emulsion. The precipitate is collected on a filter, washed several times with water and air dried in an evaporation dish. About 2 g of product is recovered having a weight average molecular weight of about 420 Daltons with a polydispersity of 1.72.

### EXAMPLE 16

### Resol Oligomer of 3,5-bis(trifluoromethyl)phenol

To a 125 mL Erlenmeyer flask is added 4.36 g of sodium hydroxide and 30 mL of de-mineralized water. To the solution is then added 25 g of 3,5-bis(trifluoromethyl)phenol followed by 35.3 g of 37% formaldehyde. The reaction mixture is then heated with agitation to about 85 to 90° C. for about 60 hours. Product separation is carried out by adding the reaction mixture to about 800 mL de-mineralized water acidified with about 11 g of concentrated hydrochloric acid. The resulting oil precipitate is separated using a separatory funnel, washed with several portions of de-mineralized water and dried using a freeze drier. About 21 g of a very viscous amber oil is recovered having a weight average molecular weight of 645 Daltons and polydispersity of 1.21. HPLC analysis shows the presence of at least eight major components one of which comprised about 32% of the product mixture.

### EXAMPLE 17

### Conversion of Resol Oligomer to Novolak Resin

The resol oligomer of Example 16 was converted to a novolak resin. A mixture of 5.0 g of oligomer from Example 16 and 0.07 g of methanesulfonic acid is heated at about 93 to 95° C. for about 17 hours. Upon cooling the product mixture is dissolved in 25 mL of dichloromethane and washed with de-mineralized water. The dichloromethane solution is concentrated on the rotary evaporator to dryness. About 4 g of a light brown solid is obtained having a weight average molecular weight of about 1170 Daltons and a polydispersity of 1.22.

The above Examples 15, 16 and 17 demonstrate that the methylol groups of highly fluorinated phenols and resols are reactive and affective as intermediates to higher molecular weight fluorinated novolaks. The fluorinated resol intermediates can be reacted with a large number of un-substituted and fluorine substituted phenols to form new resin structures suitable for lithographic applications. Furthermore the resol oligomer of Example 16 can be used to raise the fluorine content of novolak resins and render them more transparent to 157 nm radiation.

### EXAMPLE 18

### Synthesis of 4-hydroxy-2,3,5,6-tetrafluorostyrene (HTFS)

In a 500 mL round bottom flask are charged 75.00 g (386.38 mmol) of pentafluorostyrene, 75.88 g (1.35 mol) of potassium hydroxide, 200 mL of t-butanol and 25 mL of water. The reaction mixture is stirred at 50° C. for 66 h under a nitrogen atmosphere. After cooling to room temperature, 100 mL of dichloromethane is added and stirred for 30 min. The reaction mixture is then transferred slowly into a plastic beaker containing 300 mL of dilute HCl solution (2:1 mixture of concentrated HCl and water) with stirring at 0° C. About 20 g of calcium chloride is also added to convert hydrogen fluoride bi-product into CaF₂ salt. About 500 mL of dichloromethane is then added to the aqueous solution and the mixture stirred for 2 h at 0° C. The organic layer is separated and the top aqueous layer is then washed twice with 200 mL of dichloromethane. The combined organic solution is washed with 200 mL of aqueous NaCl solution, rinsed with water and dried over MgSO₄. High pressure liquid chromatography shows the product is a mixture of three major components. These components are identified by subsequent analyses to consist of 4-hydroxy-2,3,5,6-tetrafuorostyrene, 4-t-butoxy-2,3,5,6-tetrafluorostyrene and pentafluorostyrene. The isolation of 4-hydroxy-2,3,5,6-tetraflorostyrene is carried out as follows:.

To the crude product mixture in dichloromethane is added 500 mL of aqueous tetramethylammonium hydroxide (a 2:1 mixture of 0.26 N tetramethylammonium hydroxide developer and water). The mixture is vigorously mixed and the bottom organic layer, A, is removed and saved for further processing. The top aqueous layer, B, is washed with two 150 mL portions of dichloromethane and then acidified with HCl until the pH reached about 2˜3. To this acidified mixture is added 500 mL of dichloromethane to extract the product. The dichloromethylene solution is then washed with 100 mL of NaCl solution, rinsed with water and dried over MgSO₄. To the filtered solution about 15 ppm of t-butylcatechol is added and the solvent removed under reduced pressure at 15° C. About 48.2 g (64.9% yield) of a light yellow liquid is obtained with a >99% purity as determined by HPLC analysis.

### EXAMPLE 19

### 4-t-Butoxy-2,3,5,6-tetrafluorostyrene

4-t-Butoxy-2,3,5,6-tetrafluorostyrene, present in the organic layer A of Example 18, is isolated and purified by distillation.

### EXAMPLE 20

### Synthesis of poly(pentafluorostyrene)

To a 50 mL round bottom flask are charged 5.00 g (25.76 mmol) of pentafluorostyrene, 0.170 g (1.03 mmol) of AIBN radical initiator and 8.00 g of anhydrous THF. The reaction vessel is then degassed by two freeze and thaw cycles, and kept under nitrogen atmosphere. The reaction mixture is then heated with stirring at 70° C. for 18 h. To the viscous reaction mixture is added 4 mL of THF, and the solution precipitated into 600 mL of methanol. The polymer is air-dried, redissolved into 5 mL of acetone and re-precipitated into 600 mL of methanol. Upon vacuum drying for 24 h at 40 ° C. about 4.89 g of white powder is obtained (97.8% yield) with a weight average molecular weight (Mw)of about 14700, and a number average molecular weight of about (Mn) 6900 Daltons. The absorbance at 157 nm is about 3.76/μm.

### EXAMPLE 21

### Synthesis of poly(4-hydroxy-2,3,5,6-tetrafluorostyrene)

To a 50 mL round bottom flask are charged 10.00 g (52.08 mmol) of 4-hydroxy-2,3,5,6-tetrafluorostyrene of Example 18, 0.257 g (1.56 mmol) of AIBN radical initiator and 15.00 g of anhydrous THF. The reaction vessel is then degassed by two freeze and thaw cycles, and kept under nitrogen atmosphere. The reaction mixture is then heated with stirring at 70° C. for 18 h. To the viscous reaction mixture is added 5 mL of THF, and the solution precipitated into 800 mL of hexane. The polymer is collected and air-dried, re-dissolved in 15 mL of THF and re-precipitated into 800 mL of hexane. Vacuum drying at 40° C. for 24 h gives about 8.79 g of a white powder (88.0% yield) having a Mw of about 63300 Daltons and a polydispersity of 2.36. The polymer glass transition is about 76° C. with an absorbance at 157 nm of about 4.71/μm.

### EXAMPLE 22

### Synthesis of poly(4-t-butoxy-2,3,5,6-tetrafluorostyrene)

To a 50 mL round bottom flask are charged 5.00 g (20.14 mmol) of 4-t-butoxy-2,3,5,6-tetrafluorostyrene of Example 19, 0.099 g (0.604 mmol) of AIBN radical initiator and 10.00 g of anhydrous THF. The reaction vessel is degassed by two freeze and thaw cycles, and kept under a nitrogen atmosphere. The reaction mixture is then heat with stirring at 70° C. for 16 h. To the viscous reaction mixture is added 5 mL of THF, and the solution precipitated into 800 mL of methanol. The resulting polymer is collected on a filter, air-dried, re-dissolved in 10 mL of THF and re-precipitated in 800 mL of methanol. After vacuum drying at 40° C. for 24 h about 4.12 g of white powder (82.4% yield) is obtained. Gel permeation chromatography analysis shows the product to have a Mw of about 71390, a Mn of about 28650 Daltons. Differential scanning calorimetry shows a glass transition temperature for the polymer of about 106° C. The vacuum UV absorbance of the polymer at 157 nm is about 4.24/μm.

### EXAMPLE 23

### Synthesis of poly(4-hydroxy-2,3,5,6-tetrafluorostyrene-co-4-t-butoxy-2,3,5,6-tetrafluorostyrene)

To a 50 mL round bottom flask are charged 2.00 g (10.41 mmol) of 4-hydroxy-2,3,5,6-tetrafluorostyrene, 3.88 g (15.62 mmol) of 4-t-butoxy-2,3,5,6-tetrafluorostyrene, 0.256 g (1.56 mmol) of AIBN and 12 g of anhydrous THF. The reaction vessel is degassed by two freeze and thaw cycles, and kept under nitrogen atmosphere. The reaction mixture is then heated with stirring at about 700 C for about 16 h. To the viscous reaction mixture is added 5 mL of THF and the solution precipitated into about 800 mL of hexane. The polymer is collected and air-dried on the filter, re-dissolved in 10 mL of THF and re-precipitated in 800 mL of hexane. After vacuum drying at 40° C. for 24 h about 4.32 g of a white powder (73.5% yield) is obtained having a Mw of 62770 and a Mn of 28860 Daltons. The polymer composition was determined by quantitative NMR techniques to comprise of 33 mole percent of 4-hydroxy-2,3,5,6-tetrafluorostyrene and 67 mole percent of 4-t-butoxy-2,3,5,6-tetrafluorostyrene. Differential scanning calorimetry of the polymer gave a glass transition of 105° C. while the dissolution rate in a 0.26 N tetramethylammonium hydroxide developer was determined to be about 1.0 Å/s.

### EXAMPLE 24

### Synthesis of poly(4-hydroxy-2,3,5,6-tetrafluorostyrene-co-t-butylmethacrylate)

To a 50 mL round bottom flask are charged 6.00 g (31.23 mmol) of 4-hydroxy-2,3,5,6-tetrafluorostyrene, 2.96 g (20.82 mmol) of t-butylmethacrylate, 0.256 g (1.56 mmol) of AIBN and 15 g of anhydrous THF. The reaction mixture is degassed by two freeze and thaw cycles, and while under an nitrogen atmosphere is heated with stirring at about 70° C. for 16 h. To the viscous reaction mixture is added 5 mL of THF and the solution precipitated into about 1600 mL of de-mineralized water. The polymer is collected and air-dried on the filter, re-dissolved in 15 mL of THF and re-precipitated into about 1600 mL de-mineralized water. The product is vacuum dries at 50° C. for 48 h to give about 7.92 g of white powder (88.4% yield) having a Mw of about 31100 and a Mn of about 13100 Daltons. The T_{g} is 99° C. as determined by DSC and the absorbance at 157 nm is 4.95/μm.

### EXAMPLE 25

### Synthesis of poly(α-(trifluoromethyl)acrylic acid-co-2,3,4,5,6-pentafluorostyrene)

To a 50 mL round bottom flask are charged 2.50 g (17.85 mmol) of α-(trifluoromethyl)acrylic acid, 3.46 g of 2,3,4,5,6-pentafluorostyrene and 0.117 g of AIBN radical initiator. The reaction vessel is degassed using the freeze and thaw method, and kept under nitrogen atmosphere. The reaction mixture is then heated with stirring at 70° C. for 18 h. To the solidified reaction mixture is added 10 mL of THF and the mixture stirred until it completely dissolves. The product is precipitated into 800 mL of hexane, is collected on a filter and air-dried. It is then re-dissolved in 10 mL of THF and again precipitated into 800 mL of hexane. The product is collected on a filter, it is air dried followed by a final vacuum drying at 40° C. for 24 h. About 4.38 g (74% yield) of a white polymer powder is obtained having a weight average molecular weight of about 46,500 and a number average molecular weight of about 19,500 Daltons as determined by gel permeation chromatography. At 157 nm the polymer has an absorbance of 5.39/m as determined using the Acton vacuum deep UV instrument.

### EXAMPLE 26

### Synthesis of poly(4-hydroxy-2,3,5,6-tetrafluorostyrene-co-2-methyladamantylmethacrylate)

To a 50 mL round bottom flask are charged 2.00 g (10.41 mmol) of 4-hydroxy-2,3,5,6-tetrafluorostyrene, 1.63 g (6.94 mmol) of 2-methyladamantyl methacrylate, 0.085 g (0.521 mmol) of AIBN and 8 g of anhydrous THF. The reaction mixture is first degassed and then while under a nitrogen atmosphere is heated with stirring at about 70° C. for about 16 h. To the reaction mixture is then added 3 mL of THF and the solution precipitated into 800 mL of hexane. The polymer is vacuum dried for 24 h at 40° C. to give about 2.12 g of a white powder (58.4% yield) having a Mw of about 36890 and a Mn of about 18660 Daltons.

### EXAMPLE 27

### Synthesis of poly(4-hydroxy-2,3,5,6-tetrafluorostyrene-co-isobomylmethacrylate)

To a 50 mL round bottom flask are charged 2.00 g (10.41 mmol) of 4-hydroxy-2,3,5,6-tetrafluorostyrene, 1.54 g (6.94 mmol) of isobornyl methacrylate, 0.085 g (0.52 mmol) of AIBN and 8 g of anhydrous THF. The mixture is degassed and while under a nitrogen atmosphere is heated with stirring at about 70° C. for 16 h. The reaction mixture is diluted with about 3 mL of THF and the solution precipitated into 800 mL of hexane. The product was collected and air dried on the filter, re-dissolved in 7 mL of THF and re-precipitated into 800 mL of hexane. The polymer was vacuum dried at 40° C. for 24 h to give about 1.82 g of a white powder (51.4% yield) having a Mw of about 31090 and Mn of about 14750 Daltons.

### EXAMPLE 28

### Synthesis of poly(4-hydroxy-2,3,5,6-tetrafluorostyrene-co-pentafluoro-styrene-co-t-butylmethacrylate)

To a 250 mL round bottom flask are charged 3.23 g (16.81 mmol, 60 mole %) of 4-hydroxy-2,3,5,6-tetrafluorostyrene, 9.544 g (2.80 mmol, 10 mole %) of pentafluorostyrene, 1.20 g (8.41 mmol, 30 mole %) of t-butylmethacrylate, 0.276 g (1.681 mmol) of AIBN and 50 g of anhydrous THF. The reactants mixture is degassed and while under a nitrogen atmosphere is heated with stirring at 70° C. for 16 h. The reaction mixture is then concentrated and slowly added into 800 mL of hexane to precipitate the polymer. After it is air dried on the filter the product is re-dissolved in 7 mL of THF and re-precipitated from 800 mL of hexane. The product was vacuum dried at 40° C. for 24 H to provide about 2.39 g of a white powder (58.0% yield) with a Mw of about 8910 and an Mn of about 5420 Daltons. Spectroscopic analysis, using both ¹³C and ¹⁹F NMR techniques, is used to determine the mole percent of monomer incorporation into the polymer. The polymerization reaction produced a terpolymer containing about 59.34 mole % 4-hydroxy-2,3,5,6-tetrafluorostyrene, about 9.91 mole % pentafluorostyrene and about 30.75 mole % of t-butylmethacrylate. Additional characterization indicated the polymer to have a glass transition temperature of about 130° C. and a dissolution rate(in Shipley LDD-26W developer) of about 8200 Å/s.

### EXAMPLES 29 THROUGH 36

Following the procedure according to Example 28, a series of terpolymers were prepared having different monomer incorporation and characteristics. The polymer compositions and their characteristics are summarized in Table 1.

TABLE 1

| | Polymer | | | | | | |
|---|---|---|---|---|---|---|---|
| | composition(mole %)* | | | Molecular weight | | T_{g} | DR |
| Example | X** | Y** | Z** | M_{w} | Mₙ | (° C.) | (A/s) |
| 29 | 10.92 | 59.64 | 29.44 | 7810 | 5720 | 113 | 1.50 |
| 30 | 16.30 | 53.99 | 29.71 | 7720 | 5260 | 123 | 0.83 |
| 31 | 18.49 | 54.50 | 27.01 | 11900 | 8230 | 121 | |
| 32 | 21.10 | 49.33 | 29.57 | 13160 | 8770 | 127 | |
| 33 | 27.19 | 43.04 | 29.77 | 13570 | 8720 | 125 | |
| 34 | 29.67 | 37.07 | 33.26 | 13480 | 8450 | 125 | |
| 35 | 29.94 | 41.32 | 28.74 | 9330 | 6050 | 125 | 1.5 |
| 36 | 35.24 | 37.53 | 27.23 | 12360 | 7470 | 124 | |

*The polymer compositions determined using quantitative ¹³C and 19F NMR techniques.
**X: 4-Hydroxy-2,3,5,6-tetrafluorostyrene, Y: pentafluorostyrene, Z: t-butylmethacrylate.

### EXAMPLE 37

### Copolymer of 4-hydroxy-2,3,5,6-tetrafluorostyrene and Methyl 2-(trifluoromethyl)acrylate

One part of 4-hydroxy-2,3,5,6-tetrafluorostyrene and one part of methyl 2-(trifluoromethyl) acrylate are co-polymerized according to the procedure of Example 28 to produce a co-polymer in 57 percent yield with a composition consisting of 45 mole percent 4-hydroxy-2,3,5,6-tetrafluorostyrene and 55 mole percent methyl 2-(trifluoromethyl) acrylate as determined by quantitative NMR. GPC shows the polymer to have a Mw of about 3118 and a Mn of about 2099 Daltons.

### EXAMPLE 38

### Copolymer of 4-hydroxy-2,3,5,6-tetrafluorostyrene, and t-butyl 2-(trifluoromethyl)acrylate

Following the procedure according to Example 28 a copolymer of 4-hydroxy-2,3,5,6-tetrafluorostyrene and t-butyl 2-(trifluoromethyl) acrylate is prepared using equal monomer feed. The resulting copolymer was obtained in 31 percent yield has a composition, as determined by quantitative NMR, consists of 53 percent of 4-hydroxy-2,3,5,6-tetrafluorostyrene and 47 percent of t-butyl 2-(trifluoromethyl) acrylate. GPC analysis indicated the polymer to have a Mw of about 3294 and a Mn of about 2400 Daltons.

### EXAMPLE 39

### Terpolymer of 4-hydroxy-2,3,5,6-tetrafluorostyrene, Pentafluorostyrene and t-butyl 2-(trifluoromethyl)acrylate

A monomer mixture comprising of 30 mole percent of 4-hydroxy-2,3,5,6-tetrafluorostyrene, 40 mole percent of pentafluorostyrene and 30 mole percent of t-butyl 2-(trifluoromethyl)acrylate is reacted according to the procedure of Example 26 to produce a terpolymer in 58 percent yield. The polymer composition as determined by quantitative NMR consists of 29 mole percent 4-hydroxy-2,3,5,6-tetrafluorostyrene, 43 mole percent pentafluorostyrene and 28 mole percent t-butyl 2-(trifluoromethyl)acrylate. GPC analysis indicated the polymer to have a Mw of about 5838 and a Mn of about 3976 Daltons.

### EXAMPLE 40

### Copolymer of 4-tert-butoxy-2,3,5,6-tetrafluorostyrene and Heptafluorobutyl Acrylate

4-tert-butoxy-2,3,5,6-tetrafluorostyrene (5.5 g, 20.14 mmol), heptafluorobutyl acrylate (1.28 g, 5.04 mmol) and 0.17 g, 1.04 mmol of AIBN in 9.2 mL of isopropanol are reacted at reflux for 16 h. Upon cooling, 3 mL of acetone is added and the solution slowly added to excess water to precipitate the polymer. The polymer was dried for 12 h at 75° C. under vacuum. The polymer had a Mw of about 32221 and a Mn of about 9664 Daltons as determined by GPC. The 157 nm absorbance of the polymer is 4.51/μm.

### EXAMPLE 41

### Copolymer of 4-tert-butoxy-2,3,5,6-tetrafluorostyrene and heptafluorobutyl methacrylate

4-tert-butoxy-2,3,5,6-tetrafluorostyrene (5.5 g, 20.14 mmol), heptafluorobutyl methacrylate (1.35 g, 5.04 mmol) and 0.17 g, 1.04 mmol of AIBN in 9.2 mL of isopropanol are reacted at reflux for 16 h. Upon cooling, 3 mL of acetone is added and the solution slowly added to excess water to precipitate the polymer. The polymer was dried for 12 h at 75° C. under vacuum. The polymer had a Mw of about 26087 and a Mn of about 8489 Daltons as determined by GPC. The 157 nm absorbance of the polymer is 4.3 1/μm.

The foregoing description of the invention is merely illustrative thereof, and it is understood that variations and modifications can be effected without departing from the spirit or scope of the invention as set forth in the following claims.

What is claimed is:

1. A method for forming a photoresist relief image, comprising:
(a) applying a photoresist composition on a substrate, the photoresist comprising a resin and a photoactive component, the resin comprising fluorine-substituted phenolic units and photoacid-labile groups;
(b) exposing the photoresist to activating radiation and developing the exposed photoresist layer.

2. The method of claim 1 wherein the photoresist is exposed with radiation having a wavelength of less than about 200 nm.

3. The method of claim 1 wherein the photoresist is exposed with radiation having a wavelength of less than about 170 nm.

4. The method of claim 1 wherein the photoresist is exposed with radiation having a wavelength of less than about 160 nm.

5. The method of claim 1 wherein the photoresist is exposed with radiation having a wavelength about 157 nm.

6. The method of claim 1 wherein the photoresist is exposed with radiation having a wavelength of less than about 300 nm.

7. The method of any one of claims 1 through 6 wherein the resin comprises one or more photoacid generator compounds.

8. The method of any one of claims 1 through 7 wherein the resin comprises polymerized vinylphenol units.

9. The method of any one of claims 1 through 8 wherein the fluorinated phenolic units are substituted at one or more phenolic ring position by F or fluoroalkyl.

10. The method of any one of claims 1 through 8 wherein the fluorinated phenolic units are substituted at one or more phenolic ring position by F or —CF₃.

11. The method of any one of claims 1 through 10 wherein the resin comprises halogen, halogenated alkyl, nitro, nitrile, cyano, sulfinyl, or sulfonyl groups.

12. The method of any one of claims 1 through 11 wherein the resin comprises at least one other repeat unit that is distinct from the fluorinated phenolic units.

13. The method of any one of claims 1 through 11 wherein the resin comprises at least two other repeat units that are distinct from the fluorinated phenolic units.

14. The method of any one of claims 1 through 13 wherein the resin is a terpolymer.

15. The method of any one of claims 1 through 13 wherein the resin is a tetrapolymer.

16. The method of any one of claims 1 through 13 wherein the resin is a pentapolymer.

17. The method of any one of claims 1 through 16 wherein the resin comprises photoacid-labile groups that are distinct units from the fluorinated phenolic units.

18. The method of any one of claims 1 through 16 wherein the resin comprises photoacid-labile groups that are present on the fluorinated phenolic units.

19. The method of any one of claims 1 through 18 wherein the resin comprises photoacid-labile groups that are ester groups, acetal groups, ketal groups or formal groups.

20. The method of any one of claims 1 through 18 wherein the resin further comprises photoacid-labile alkyl acrylate units.

21. The method of any one of claim 1 through 20 wherein the resin comprises optionally substituted polymerized styrene units that do not contain hydroxy, carboxy or photoacid labile ring substituents.

22. The method of any one of claims 1 through 8 wherein the resin consists essentially of 1) the fluorinated phenolic units and 2) alkyl acrylate photoacid-labile units.

23. The method of any one of claims 1 through 8 wherein the resin-consists essentially of 1) the fluorinated phenolic units, 2) alkyl acrylate photoacid-labile units, and 3) optionally substituted polymerized styrene units that do not contain hydroxy, carboxy or photoacid labile ring substituents.

25. A photoresist comprising a resin and a photoactive component, the resin comprising fluorine-substituted phenolic units and photoacid-labile groups.

26. The photoresist of claim 25 wherein the photoresist comprises one or more photoacid generator compounds.

27. The photoresist of claim 25 or 26 wherein the resin comprises polymerized fluorinated vinylphenol units.

28. The photoresist of any one of claims 25 through 27 wherein the fluorinated phenolic units are substituted at one or more phenolic ring position by F, fluoroalkyl, or fluoroether.

29. The photoresist of any one of claims 25 through 28 wherein the fluorinated phenolic units are substituted at one or more phenolic ring position by F or —CF_{3.}

30. The photoresist of any one of claims 25 through 29 wherein the resin comprises halogen, halogenated alkyl, nitro, nitrile, cyano, sulfinyl, or sulfonyl groups.

31. The photoresist any one of claims 25 through 30 wherein the resin comprises at least one other repeat unit that is distinct from the fluorinated phenolic units.

32. The photoresist of any one of claims 25 through 30 wherein the resin comprises at least two other repeat units that are distinct from the fluorinated phenolic units.

33. The photoresist of any one of claims 25 through 32 wherein the resin is a terpolymer.

34. The photoresist of any one of claims 25 through 32 wherein the resin is a tetrapolymer.

35. The photoresist of any one of claims 25 through 32 wherein the polymer is a pentapolymer.

36. The photoresist of any one of claims 25 through 35 wherein the resin comprises photoacid-labile groups that are distinct units from the fluorinated phenolic units.

37. The photoresist of any one of claims 25 through 35 wherein the resin comprises photoacid-labile groups that are present on the fluorinated phenolic units.

38. The photoresist of any one of claims 25 through 37 wherein the resin comprises photoacid-labile groups that are ester groups, acetal groups, ketal groups or formal groups.

39. The photoresist of any one of claims 25 through 38 wherein the resin further comprises photoacid-labile alkyl acrylate units.

40. The photoresist of any one of claim 25 through 39 wherein the resin comprises optionally substituted polymerized styrene units that do not contain hydroxy, carboxy or photoacid labile ring substituents.

41. The photoresist of any one of claims 25 through 40 wherein the resin consists essentially of 1) the fluorinated phenolic units and 2) alkyl acrylate photoacid-labile units.

42. The photoresist of any one of claims 25 through 40 wherein the resin consists essentially of 1) the fluorinated phenolic units, 2) alkyl acrylate photoacid-labile units, and 3) optionally substituted polymerized styrene units that do not contain hydroxy, carboxy or photoacid labile ring substituents.

43. An article of manufacture comprising a substrate having thereon a photoresist of any one of claims 25 through 42.

44. An article of claim 43 wherein the substrate is a microelectronic wafer or an optical-electronic substrate.

45. An optionally protected alkenetetrafluorophenol compound.

46. The compound of claim 45 wherein the compound is C₆F₄(OH)(C₂₋₁₂alkene).

47. The compound of claim 45 that is optionally protected 4-hydroxy-2,3,5,6-tetrafluorostyrene, 3-hydroxy-2,4,5,6-tetrafluorostyrene, 4-hydroxy-2,3,5,6-tetrafluoro(α-methylstyrene), 3-hydroxy-2,4,5,6-tetrafluoro(α-methylstyrene)styrene, 4-hydroxy-2,3,5,6-tetrafluoro(α-trifluoromethylstyrene), or 3-hydroxy-2,4,5,6-tetrafluoro(α-trifluoromethylstyrene).

48. The compound of any one of claims 45 through 47 wherein one or more of the alkene carbons are is fluorinated at one or more available positions.

49. The compound of any one of claims 45 through 48 wherein the phenol compound is fluoro-substituted at 2, 3, 5, 6 positions.

50. The compound of claim 48 or 49 wherein the alkene carbons or the phenol are fluorinated by F or triflouromethyl.
